(19) United States
(12) Patent Application Publication
(10) Pub. No.: US 2014/0001598 A1
(43) Pub. Date: Jan. 2, 2014

(54) ATOMIC LAYER DEPOSITION (ALD) OF TAALC FOR CAPACITOR INTEGRATION

(71) Applicants: Nick Lindert, Beaverton, OR (US); Ruth A. Brain, Portland, OR (US); Joseph M. Steigerwald, Forest Grove, OR (US); Timothy E. Glassman, Portland, OR (US); Andre Baran, Portland, OR (US)

(72) Inventors: Nick Lindert, Beaverton, OR (US); Ruth A. Brain, Portland, OR (US); Joseph M. Steigerwald, Forest Grove, OR (US); Timothy E. Glassman, Portland, OR (US); Andre Baran, Portland, OR (US)

(21) Appl. No.: 13/977,550

(22) PCT Filed: Dec. 21, 2011
(86) PCT No.: PCT/US11/66493

§ 371 Date: Jun. 28, 2013

(51) Int. Cl. H01L 49/02

(52) U.S. Cl. CPC H01L 28/60
USPC 257/534

(57) ABSTRACT

Atomic layer deposition (ALD) of TaAlC for capacitor integration is generally described. For example, a semiconductor structure includes a plurality of semiconductor devices disposed in or above a substrate. One or more dielectric layers are disposed above the plurality of semiconductor devices. A metal-insulator-metal (MIM) capacitor is disposed in at least one of the dielectric layers, the MIM capacitor includes an electrode having a conformal layer of TaAlC and the MIM capacitor is electrically coupled to one or more of the semiconductor devices. Other embodiments are also disclosed and claimed.

### TECHNICAL FIELD

Embodiments of the invention are in the field of embedded capacitors and, in particular, atomic layer deposition (ALD) of TaAlC for capacitor integration.

### BACKGROUND

For the past several decades, the scaling of features in integrated circuits has been a driving force behind an ever-growing semiconductor industry. Scaling to smaller and smaller features enables increased densities of functional units on the limited real estate of semiconductor chips. For example, shrinking transistor size allows for the incorporation of an increased number of memory devices on a chip, lending to the fabrication of products with increased capacity. The drive for ever-more capacity, however, is not without issue. The necessity to manufacture each device without even slight imperfections becomes increasingly significant.

In metal-insulator-metal (MIM) capacitors, such as, for example the MIM capacitors described in patent application Ser. No. 13/041,170, entitled “Semiconductor Structure Having a Capacitor and Metal Wiring Integrated in a Same Dielectric Layer,” by Nick Lindert filed on Mar. 4, 2011, which is herein incorporated by reference in its entirety, it is important to protect the insulator from copper diffusion and ensure the metal layers don't contain voids or imperfections created by processing steps.

### BRIEF DESCRIPTION OF THE DRAWINGS

FIG. 1 is a graphical illustration of a cross-sectional view of an example metal-insulator-metal (MIM) capacitor including ALD of TaAlC, in accordance with an embodiment of the present invention.

FIG. 2 is a graphical illustration of a cross-sectional view of an example MIM capacitor including ALD of TaAlC, in accordance with an embodiment of the present invention.

FIG. 3 is a graphical illustration of a cross-sectional view of an example MIM capacitor including ALD of TaAlC, in accordance with an embodiment of the present invention.

FIG. 4 is a flowchart of an example method of atomic layer deposition (ALD) of TaAlC for capacitor integration, in accordance with an embodiment of the present invention.

FIG. 5 is a block diagram of an example electronic appliance suitable for atomic layer deposition (ALD) of TaAlC for capacitor integration, in accordance with an embodiment of the present invention.

### DETAILED DESCRIPTION

Atomic layer deposition (ALD) of TaAlc for capacitor integration is described. In the following description, numerous specific details are set forth, such as specific metal layers and materials, in order to provide a thorough understanding of embodiments of the present invention. It will be apparent to one skilled in the art that embodiments of the present invention may be practiced without these specific details. In other instances, well-known features, such as integrated circuit design layouts, are not described in detail in order to not unnecessarily obscure embodiments of the present invention. Furthermore, it is to be understood that the various embodiments shown in the Figures are illustrative representations and are not necessarily drawn to scale.

In an aspect of the present invention, an embedded metal-insulator-metal (MIM) capacitor includes a conformal MIM layer of TaAlC. For example, FIG. 1 illustrates a cross-sectional view of an example MIM capacitor, in accordance with an embodiment of the present invention. Device 100 may include substrate 102, first dielectric layer 104, copper wiring 106, second dielectric layer 108, and MIM 110, including bottom electrode 112, insulator layer 114, and top electrode 116.

In an embodiment, substrate 102 is composed of a material suitable for semiconductor device fabrication. In one embodiment, substrate 102 is a bulk substrate composed of a single crystal of a material which may include, but is not limited to, silicon, germanium, silicon-germanium or a III-V compound semiconductor material. In another embodiment, substrate 102 includes a bulk layer with a top epitaxial layer. In a specific embodiment, the bulk layer is composed of a single crystal of a material which may include, but is not limited to, silicon, germanium, silicon-germanium, a III-V compound semiconductor material or quartz, while the top epitaxial layer is composed of a single crystal layer which may include, but is not limited to, silicon, germanium, silicon-germanium or a III-V compound semiconductor material. In another embodiment, substrate 102 includes a top epitaxial layer on a middle insulator layer which is above a lower bulk layer. The top epitaxial layer is composed of a single crystal layer which include, but is not limited to, silicon (e.g., to form a silicon-on-insulator (SOI) semiconductor substrate), germanium, silicon-germanium or a compound semiconductor material. The middle insulator layer is composed of a material which may include, but is not limited to, silicon dioxide, silicon nitride or silicon oxy-nitride. The lower bulk layer is composed of a single crystal which may include, but is not limited to, silicon, germanium, silicon-germanium, a III-V compound semiconductor material or quartz. Substrate 102 may further include dopant impurity atoms.

In accordance with an embodiment of the present invention, substrate 102 has thereon or therein an array of complementary metal-oxide-semiconductor (CMOS) transistors fabricated in a silicon substrate and encased in a dielectric layer. A plurality of metal interconnects may be formed above the transistors, and on a surrounding dielectric layer, and are used to electrically connect the transistors to form an integrated circuit. In one embodiment, the integrated circuit is used for a DRAM.

First dielectric layer 104 may be formed on substrate 102 and include copper wiring 106. Copper wiring 106 may represent a via, a metal wiring, or an actual contact structure formed between the bottom of MIM capacitor 110 and a semiconductor device. In an embodiment, copper wiring 1106 is electrically coupled to one or more semiconductor devices included in a logic circuit, and the MIM capacitor 110 is an embedded dynamic random access memory (eDRAM) capacitor. Top electrode 116 of MIM capacitor 110 may be connected by a via from an interconnect or metal wiring layer (not shown) above MIM capacitor 110. In one embodiment, such a connection provides the common or ground connection of the eDRAM.

In an embodiment, the MIM capacitor 110 is disposed in a trench disposed in second dielectric layer 108. MIM capacitor 110 includes a cup-shaped metal bottom electrode 112 disposed along the bottom and sidewalls of the trench. Insulator layer 114 is disposed on and conformal with the bottom electrode 112. Top electrode 116 is disposed on insulator layer 114. Insulator layer 114 isolates top electrode 116 from bottom electrode 112.

In an embodiment, top electrode 116 and bottom electrode 112 are composed of a conformal layer of TaAlC formed by atomic layer deposition (ALD). In an embodiment, one of top electrode 116 or bottom electrode 112 is composed of TaAlC, while the other is composed of a different metal. In one embodiment, the TaAlC in top electrode 116 or bottom electrode 112 comprises an atomic composition of about 42% tantalum, 6% aluminum, and 52% carbon. One skilled in the art could recognize that this material in a conformal layer could provide a copper diffusion barrier and withstand further processing steps, for example wet cleans. In alternative embodiments, top electrode 116 or bottom electrode 112 include a multiple layer structure.

In an embodiment, insulator layer 114 is composed a high-K dielectric layer. In one embodiment, insulator layer 114 is formed by an atomic vapor deposition process or a chemical vapor deposition process and is composed of a material such as, but not limited to, silicon oxy-nitride, hafnium oxide, zirconium oxide, hafnium silicate, hafnium oxy-nitride, titanium oxide, or lanthanum oxide. In another embodiment, however, insulator layer 114 is composed of silicon dioxide.

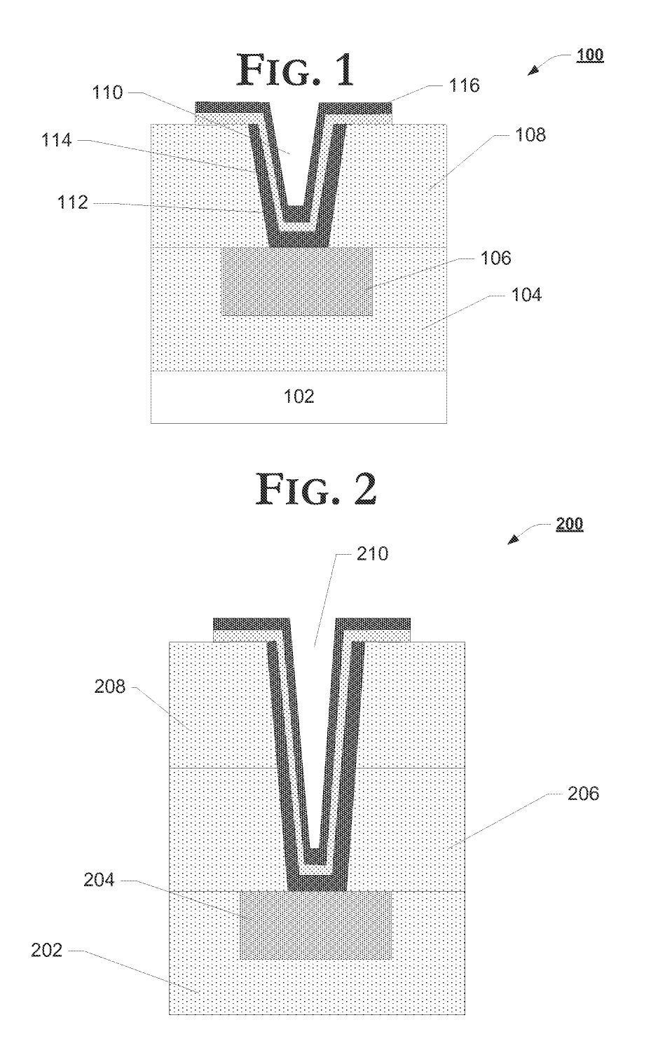

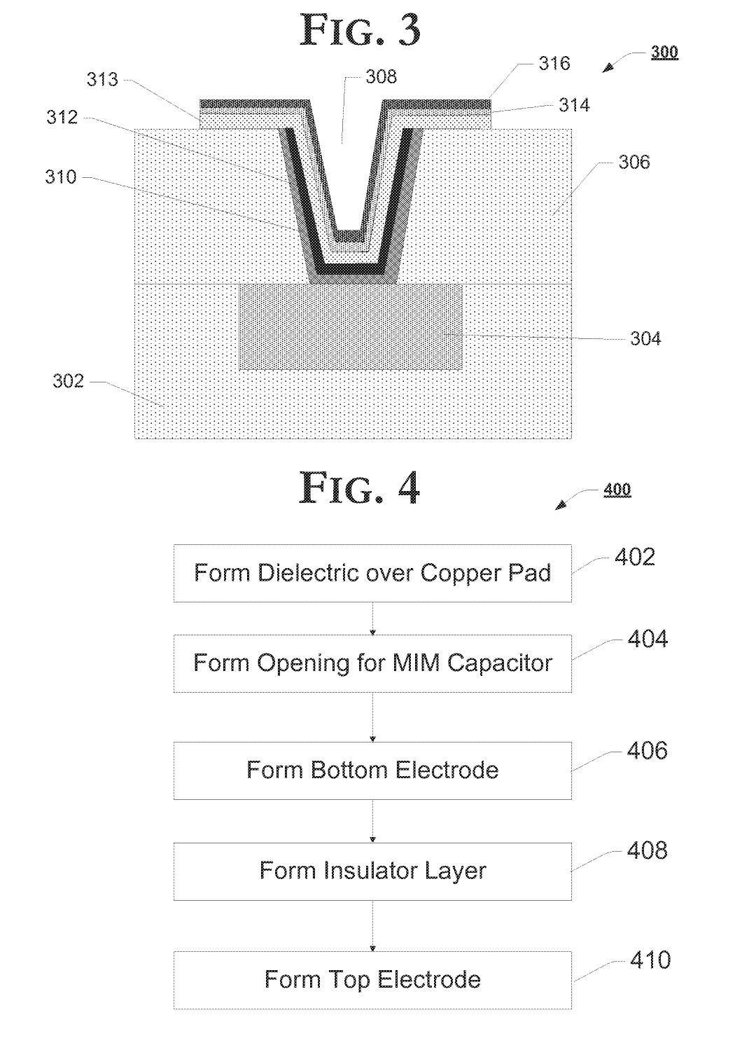

Referring to FIG. 2, a graphical illustration of a cross-sectional view of an example MIM capacitor including ALD of TaAlC, in accordance with an embodiment of the present invention, is presented. As shown in device 200, MIM capacitor 210, which may have a top or bottom electrode comprising TaAlC formed by ALD, is disposed in two separate dielectric layers 206 and 208 and is electrically coupled with copper wiring 204 in dielectric layer 202. While shown as being disposed in two dielectric layers, MIM capacitor 210 may be disposed in three or more dielectric layers in other embodiments. MIM capacitor 210 may have substantially vertical sidewalls.

Referring to FIG. 3, a graphical illustration of a cross-sectional view of an example MIM capacitor including ALD of TaAlC, in accordance with an embodiment of the present invention, is presented. Device 300 may include MIM capacitor 308 disposed in dielectric layer 306 and electrically coupled with copper wiring 304 in dielectric layer 302. As shown, MIM capacitor 308 may include multiple top electrode metal layers (314 and 316) and multiple bottom electrode metal layers (310 and 312) which are isolated by insulator layer 313. In one embodiment, bottom electrode metal layer 310 comprises TiN formed by sputtering and bottom electrode metal layer 312 comprises TaAlC formed by ALD. In one embodiment, top electrode metal layer 314 comprises Ta and top electrode metal layer 316 comprises TaAlC formed by ALD.

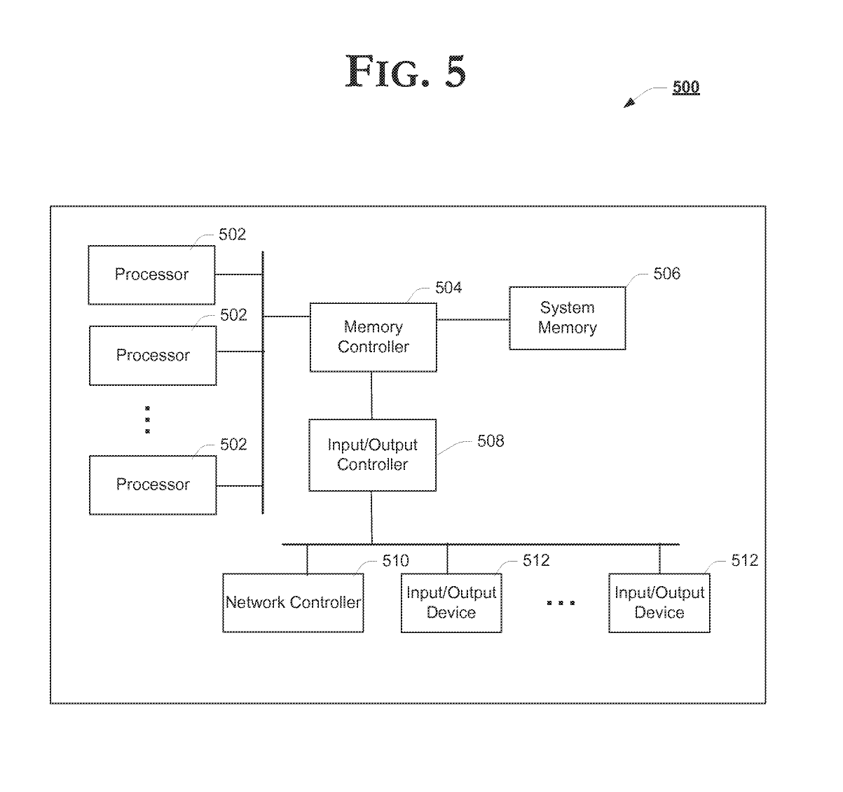

FIG. 4 is a flowchart of an example method of atomic layer deposition (ALD) of TaAlC for capacitor integration, in accordance with an embodiment of the present invention.

Referring to operation 402 of Flowchart 400, one or more dielectric layers are formed over a copper pad.

Referring to operation 404 of Flowchart 400, an opening, which exposes the copper pad is formed in the dielectric layer(s) for a MIM capacitor. In one embodiment, the opening forms a cup shape. In one embodiment, the opening has vertical or nearly vertical sidewalls.

Referring to operation 406 of Flowchart 400, a bottom electrode is formed with contacts the copper pad. In an embodiment, forming the bottom electrode includes ALD of TaAlC. In one embodiment, forming the bottom electrode includes sputtering TiN followed by ALD of TaAlC.

Referring to operation 408 of Flowchart 400, an insulator layer is formed over the bottom electrode. In an embodiment, the insulator layer comprises high-K dielectrice. In one embodiment, the insulator layer is formed by vapor deposition.

Referring to operation 410 of Flowchart 400, a top electrode is formed over the insulator layer. In an embodiment, forming the top electrode includes ALD TaAlC. In one embodiment, forming the top electrode includes sputtering Ta followed by ALD of TaAlC. Further processing steps, such as forming additional dielectric layers and electrical contacts, will occur to one skilled in the art to, for example, form an eDRAM device.

FIG. 5 is a block diagram of an example electronic appliance suitable for atomic layer deposition (ALD) of TaAlC for capacitor integration, in accordance with one example embodiment of the invention. Electronic appliance 500 is intended to represent any of a wide variety of traditional and non-traditional electronic appliances, laptops, cell phones, wireless communication subscriber units, personal digital assistants, or any electric appliance that would benefit from the teachings of the present invention. In accordance with the illustrated example embodiment, electronic appliance 500 may include one or more of processor(s) 502, memory controller 504, system memory 506, input/output controller 508, network controller 510, and input/output device(s) 512 coupled as shown in FIG. 5. One or more components of electronic appliance 500 (for example, processor(s) 502 or system memory 506) may include MIM capacitors having a conformal layer of TaAlC described previously as an embodiment of the present invention.

Processor(s) 502 may represent any of a wide variety of control logic including, but not limited to one or more of a microprocessor, a programmable logic device (PLD), programmable logic array (PLA), application specific integrated circuit (ASIC), a microcontroller, and the like, although the present invention is not limited in this respect. In one embodiment, processors(s) 502 are Intel® compatible processors. Processor(s) 502 may have an instruction set containing a plurality of machine level instructions that may be invoked, for example by an application or operating system.

Memory controller 504 may represent any type of chipset or control logic that interfaces system memory 506 with the other components of electronic appliance 500. In one embodiment, the connection between processor(s) 502 and memory controller 504 may be a high speed/frequency serial link including one or more differential pairs. In another embodiment, memory controller 504 may be incorporated into processor(s) 502 and differential pairs may directly connect processor(s) 502 with system memory 506.

System memory 506 may represent any type of memory device(s) used to store data and instructions that may have been or will be used by processor(s) 502. Typically, though the invention is not limited in this respect, system memory 506 will consist of dynamic random access memory (DRAM). In one embodiment, system memory 506 may consist of Rambus DRAM (RDRAM). In another embodiment, system memory 506 may consist of double data rate synchronous DRAM (DDRSDRAM).

Input/output (I/O) controller 508 may represent any type of chipset or control logic that interfaces I/O device(s) 512 with the other components of electronic appliance 500. In one embodiment, I/O controller 508 may be referred to as a south bridge. In another embodiment, I/O controller 508 may comply with the Peripheral Component Interconnect (PCI) Express™ Base Specification, Revision 1.0a, PCI Special Interest Group, released Apr. 15, 2003.

Network controller 510 may represent any type of device that allows electronic appliance 500 to communicate with other electronic appliances or devices. In one embodiment, network controller 510 may comply with a The Institute of Electrical and Electronics Engineers, Inc. (IEEE) 802.11b standard (approved Sep. 16, 1999, supplement to ANSI/IEEE Std 802.11, 1999 Edition). In another embodiment, network controller 510 may be an Ethernet network interface card.

Input/output (I/O) device(s) 512 may represent any type of device, peripheral or component that provides input to or processes output from electronic appliance 500.

It is to be understood that even though numerous characteristics and advantages of various embodiments of the present invention have been set forth in the foregoing description, together with details of the structure and function of various embodiments of the invention, this disclosure is illustrative only. In some cases, certain subassemblies are only described in detail with one such embodiment. Nevertheless, it is recognized and intended that such subassemblies may be used in other embodiments of the invention. Changes may be made in detail, especially matters of structure and management of parts within the principles of the embodiments of the invention to the full extent indicated by the broad general meaning of the terms in which the appended claims are expressed.

Having disclosed exemplary embodiments and the best mode, modifications and variations may be made to the disclosed embodiments while remaining within the scope of the embodiments of the invention as defined by the following claims.

What is claimed is:

1. A semiconductor structure, comprising:
a plurality of semiconductor devices disposed in or above a substrate;
one or more dielectric layers disposed above the plurality of semiconductor devices; and
a metal-insulator-metal (MIM) capacitor disposed in at least one of the dielectric layers, the MIM capacitor including an electrode having a conformal layer of TaAlC and the MIM capacitor electrically coupled to one or more of the semiconductor devices.

2. The semiconductor structure of claim 1, wherein the MIM capacitor is an embedded dynamic random access memory (eDRAM) capacitor.

3. The semiconductor structure of claim 1 further comprising the MIM capacitor including both electrodes having conformal TaAlC layers.

4. The semiconductor structure of claim 1 further comprising a top electrode of the MIM capacitor including a layer of TiN adjacent the conformal layer of TaAlC.

5. The semiconductor structure of claim 1, further cot uprising a bottom electrode of the MIM capacitor including a layer of Ta adjacent the conformal layer of TaAlC.

6. The semiconductor structure of claim 1, wherein the TaAlC comprises an atomic composition of about 42% Ta, 6% Al, and 52% C.

7. The semiconductor structure of claim 1, wherein the MIM capacitor is disposed in more than one of the dielectric layers.

8. The semiconductor structure of claim 1, wherein the MIM capacitor further comprises substantially vertical sidewalls.

9. A semiconductor structure, comprising:
one or more dielectric layers disposed above a substrate; and
a cup-shaped metal-insulator-metal (MIM) capacitor disposed in at least one of the dielectric layers, the MIM capacitor including a top electrode having a conformal layer of TaAlC and the MIM capacitor electrically coupled to a copper pad in the substrate.

10. The semiconductor structure of claim 9, further comprising MIM capacitor including a bottom electrode having a conformal layer of TaAlC.

11. The semiconductor structure of claim 9, wherein the TaAlC comprises an a composition of about 42% Ta, 6% Al, and 52% C.

12. The semiconductor structure of claim 9, wherein the top electrode further comprises a layer of TiN.

13. The semiconductor structure of claim 9, wherein the MIM capacitor s disposed in more than one of the dielectric layers.

14. The semiconductor structure of claim 9, wherein the MIM capacitor further comprises substantially vertical sidewalls.

15. A semiconductor structure, comprising:
one or more dielectric layers disposed above a substrate; and
a cup-shaped metal-insulator-metal (MIM) capacitor disposed in at least one of the dielectric layers, the MIM capacitor including a bottom electrode having a conformal layer of TaAlC and the MIM capacitor electrically coupled to a copper pad in the substrate.

16. The semiconductor structure of claim 15, further comprising the MIM capacitor including a top electrode having a conformal layer of TaAlC.

17. The semiconductor structure of claim 15, wherein the TaAlC comprises an atomic composition of about 42% Ta, 6% Al, and 52% C.

18. The semiconductor structure of claim 15, wherein the bottom electrode further comprises a layer of Ta.

19. The semiconductor structure of claim 15, wherein the MIM capacitor is disposed in more than one of the dielectric layers.

20. The semiconductor structure of claim 15, wherein the MIM capacitor further comprises substantially vertical sidewalls.
